(19) United States
(12) Patent Application Publication
(10) Pub. No.: US 2002/0072168 A1
(43) Pub. Date: Jun. 13, 2002

(54) Method of fabricating CMOS with different gate dielectric layers

(76) Inventor: Horng-Huei Tseng, Hsinchu (TW)

Correspondence Address: BACON & THOMAS, 4th Floor, 625 Slaters Lane, Alexandria, VA, 22314, US

(21) Appl. No.: 09/726,037

(22) Filed: Nov. 30, 2000

(51) Int. Cl. H01L 21/8238; H01L 21/8234; H01L 21/336

(52) U.S. Cl. 438/231; 438/275; 438/287

(57) ABSTRACT

A method of manufacturing CMOS with different gate dielectric layers on a substrate is disclosed. There are a P-well and a N-well on said substrate, an isolation region between said P-well and N-well. The method comprises the steps of: depositing a first dielectric layer on said P-well; depositing a second dielectric layer on said N-well; forming a first gate electrode over said P-well a second gate electrode over said N-well.

### FIELD OF THE INVENTION

The present invention relates generally to a method for fabricating CMOS and in particular relates to a process with different dielectric layer.

### BACKGROUND OF THE INVENTION

Since semiconductor technologies were applied to manufacture integrated circuits (IC), IC designers always wish to create smaller scale, high speed and high-density devices at an ever fasten pace. In the past two decades, therefore, constantly striving to increase chip level and to reduce semiconductor device size become a trend in IC industry. As the packing density of devices increases and the spaces among devices become closer and closer, the devices manufactured in and on the semiconductor substrate, such as transistors and capacitors undoubtly have to be made smaller and smaller. The alignment and lithography technologies are naturally more important than ever because of the continuous shrinkage of semiconductor devices.

So far, there has been some essential IC elements created, like PMOS, NMOS. Furthermore, some advanced IC elements are also created, like CMOS. CMOS, which is a combination of one PMOS and one NMOS, is usually applied to logical units—for instance, microprocessor and microcontrollers. To execute some particular purposes in the CMOS, the gate dielectric layers in the PMOS and NMOS will be manufactured with different material. However, this kind of fabrication usually higher the processing cost and processing time because of its too many masks in tradition.

In the present invention, a new method of CMOS fabrication with different gate dielectric is disclosed and processed with fewer masks.

### SUMMARY OF THE INVENTION

The present invention provides a method for manufacturing CMOS with different gate dielectric layers.

Still, the present invention provides a method for manufacturing different gate dielectric layers of the CMOS with only one mask in the processing dielectric layer steps.

First, there are a P-well and a N-well in the substrate, and an isolation region 101 between the P-well and N-well. The first dielectric layer, composed of silicon nitride, is deposited over the substrate with the thickness about 10 to 300 angstroms. The first dielectric layer is patterned to form the first dielectric layer on the P-well.

Then, a second dielectric layer with the thickness about 10 to 300 angstroms is formed on the N-well by the thermal oxidation process. A polysilicon layer is formed over the substrate with the thickness about 1000 to 3500 angstroms and is processed with lithopraphy and etching steps to define the gate electrode. The substrate is processed with LDD method to form L_{DD} region using the gate electrode as a mask. The spacer is formed on the sidewall of the two gate electrode and the source/drain region is formed by ion implantation using the spacer as a mask.

For the preferred embodiment, the third dielectric layer with the thickness about 10 to 300 angstroms can be formed on the first dielectric layer and the second dielectric layer. The third dielectric layer is composed of silicon nitride, which is the same with the first dielectric layer.

### BRIEF DESCRIPTION OF THE DRAWINGS

The objects, features and advantages of the present invention will be apparent from the following more particularly description of the invention illustrated in the accompanying drawings, in which:

FIG. 1A is a cross sectional view of a semiconductor substrate illustrating the step of depositing the first dielectric layer on the substrate in accordance with the present invention.

FIG. 1B is a cross sectional view of a semiconductor substrate illustrating the step of patterning the first dielectric layer in accordance with the present invention.

FIG. 1C is a cross sectional view of a semiconductor substrate illustrating the step of forming the second dielectric layer on the substrate in accordance with the present invention.

FIG. 1D is a cross sectional view of a semiconductor substrate illustrating the step of forming the NMOS and PMOS on the substrate in accordance with the present invention.

FIG. 2A is a cross sectional view of a semiconductor substrate illustrating the step of depositing the first dielectric layer on the substrate in accordance with the present invention.

FIG. 2B is a cross sectional view of a semiconductor substrate illustrating the step of patterning the first dielectric layer in accordance with the present invention.

FIG. 2C is a cross sectional view of a semiconductor substrate illustrating the step of forming the second dielectric layer on the substrate in accordance with the present invention.

FIG. 2D is a cross sectional view of a semiconductor substrate illustrating the step of forming the third dielectric layer on the substrate in accordance with the present invention.

FIG. 2E is a cross sectional view of a semiconductor substrate illustrating the step of forming the NMOS and PMOS on the substrate in accordance with the present invention.

### DETAILED DESCRIPTION OF THE PREFERRED EMBODIMENT

Hereinafter, the preferred embodiments of the invention will be described with reference to accompany drawing wherein like reference numerals designate like parts, respectively. There are three embodiments in the present invention.

The First embodiment

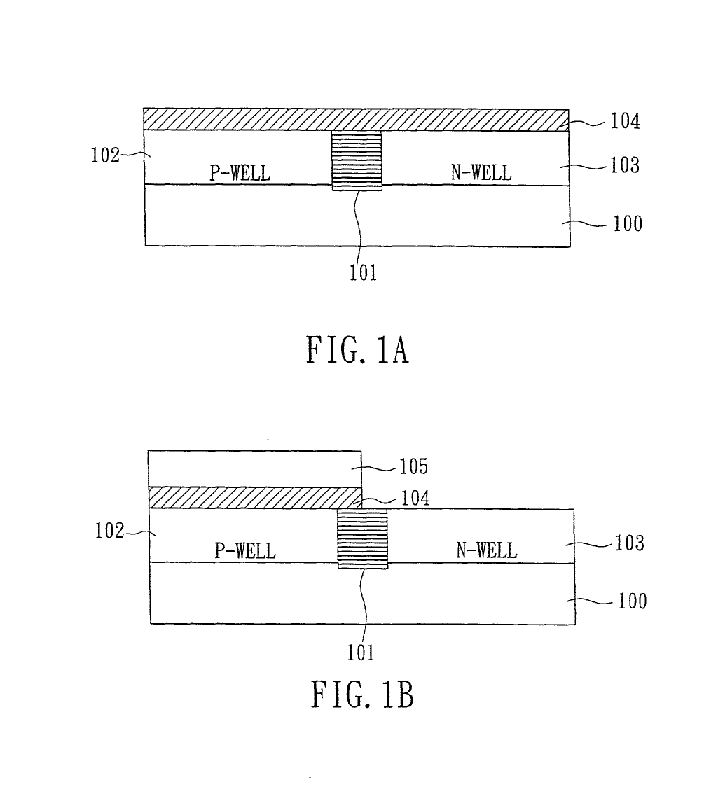

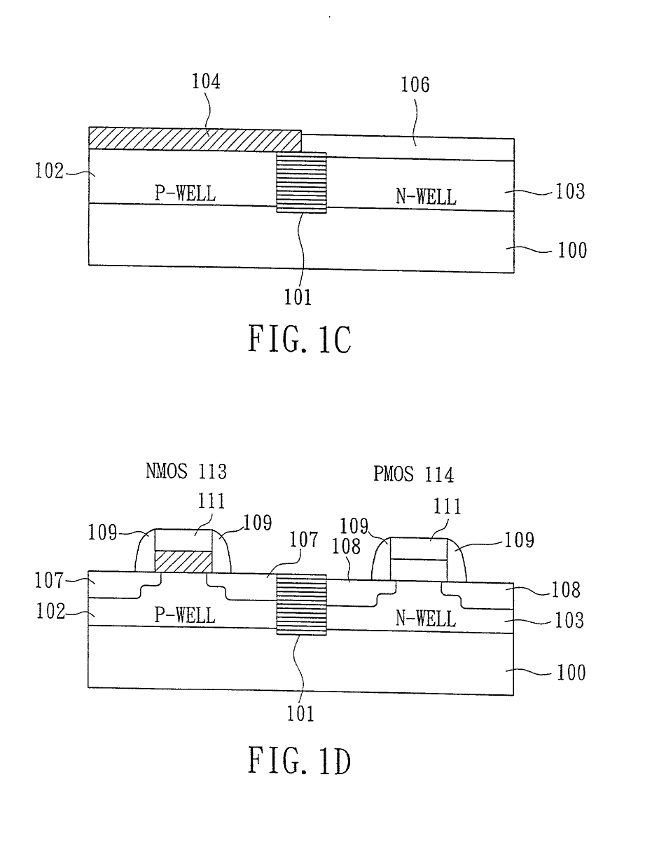

Referring to FIG. 1A, it is a cross sectional view of a semiconductor substrate illustrating the step of depositing the first dielectric layer 104 on the substrate 100 in accordance with the present invention. A single crystal substrate 100 with a <100> crystallographic orientation is used for preferred embodiment. There are a P-well 102 and a N-well 103 in the substrate 100. An isolation region 101, is between the p-well 102 and N-well 103 to provide the electrical isolation between the P-well 102 and N-well 103. For the preferred embodiment of the present invention, the isolation region 101 is the shallow trench isolation (STI). The P-well 102 and N-well 103 is performed by the ion implantation method with different ion. The first dielectric layer 104 is deposited over the substrate 100 by the blanket method. The thickness of the first dielectric layer is about 10 to 300 angstroms. For the preferred embodiment, the first dielectric layer 104 is composed of silicon nitride material.

Referring to FIG. 1B, it is a cross sectional view of a semiconductor substrate illustrating the step of patterning the first dielectric layer 104 in accordance with the present invention. A photoresist layer 105 is deposited on the first dielectric layer 104 and the photoresist layer 105 is patterned by the conventional lithography method. Then, the first dielectric layer 104 is etched using the patterned photoresist layer 105 as a mask. The first dielectric layer 104 is etched by dry etching process such as plasma etching or reactive ion etching process to form a first dielectric 104 layer on the P-well.

Referring to FIG. 1C, it is a cross sectional view of a semiconductor substrate illustrating the step of forming the second dielectric layer 106 on the substrate 100 in accordance with the present invention. The second dielectric layer 106 is formed on the portion without first dielectric layer 104 by the thermal oxidation process. That is the second dielectric layer 106 comprising silicon dioxide is formed on the N-well 103. The thickness of the second dielectric layer 106 is about 10 to 300 angstroms. The thickness of the first dielectric layer 104 and second dielectric layer 106 will be different. However, the difference between these two layers is too little to effect the embodiment of the present invention.

Referring to FIG. 1D, it is a cross sectional view of a semiconductor substrate illustrating the step of forming the NMOS 113 and PMOS 114 on the substrate 100 in accordance with the present invention. As the traditional method to form MOS, the polysilicon layer 111 is formed over the substrate 100 with the thickness about 1000 to 3500 angstroms and is processed with lithopraphy and etching steps to define the gate electrode. Then, the substrate 100 is processed with LDD method to form L_{DD} region (not shown in the figure) using the gate electrode as a mask. The spacer 109 is formed on the sidewall of the two gate electrode and the source/drain region 107, 108 is formed by ion implantation using the spacer 109 as a mask.

Take a mention that the NMOS 113 comprises the first dielectric layer 104—silicon nitride layer, and the PMOS 114 comprises the second dielectric layer 106—silicon dioxide in the formentioned embodiment. However, it is possible to manufacture the variable embodiment based on the spirit of the present invention. For example, the first dielectric layer 104 is formed on the N-well 103 instead of the P-well 102. So, the PMOS 114 comprises the first dielectric layer 104—silicon nitride layer, and the NMOS 113 comprises the second dielectric layer 106—silicon dioxide.

The Second embodiment

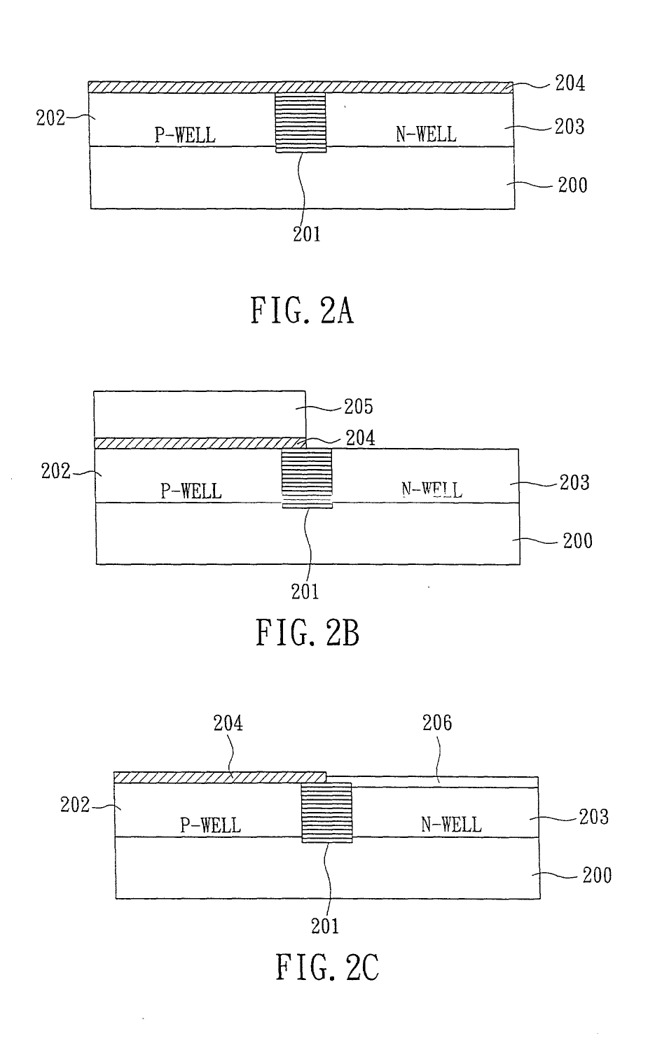

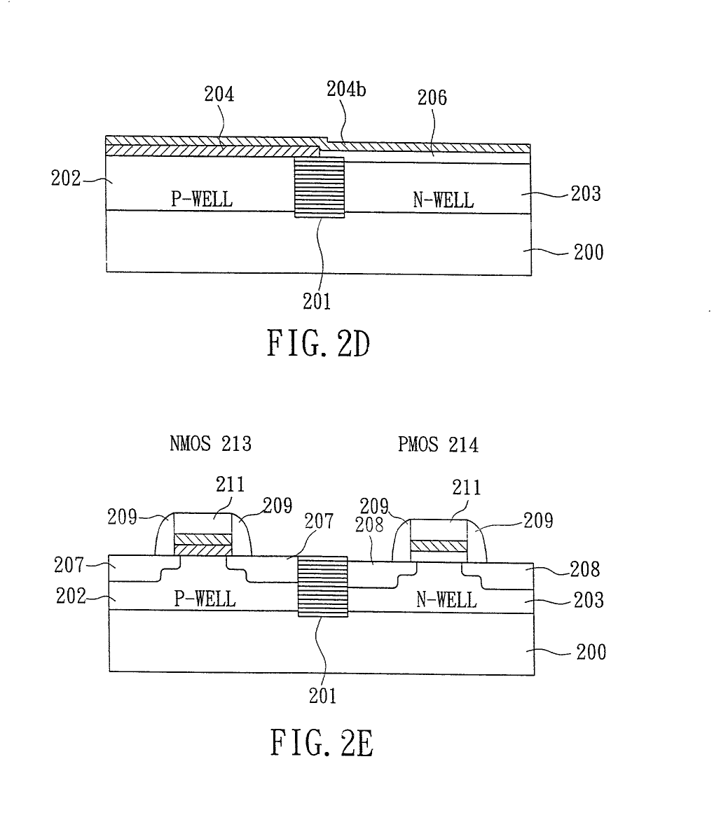

Referring to FIG. 2A, it is a cross sectional view of a semiconductor substrate illustrating the step of depositing the first dielectric layer 204 on the substrate 200 in accordance with the present invention. A single crystal substrate 200 with a <100> crystallographic orientation is used for preferred embodiment. There are a P-well 202 and a N-well 203 in the substrate 200. An isolation region 201, is between the p-well 202 and N-well 203 to provide the electrical isolation between the P-well 202 and N-well 203. For the preferred embodiment of the present invention, the isolation region 201 is the shallow trench isolation (STI). The P-well 202 and N-well 203 is performed by the ion implantation method with different ion. The first dielectric layer 204 is deposited over the substrate 200 by the blanket method. The thickness of the first dielectric layer is about 10 to 300 angstroms. For the preferred embodiment, the first dielectric layer 204 is composed of silicon nitride material.

Referring to FIG. 2B, it is a cross sectional view of a semiconductor substrate illustrating the step of patterning the first dielectric layer 204 in accordance with the present invention. A photoresist layer 205 is deposited on the first dielectric layer 204 and the photoresist layer 205 is patterned by the conventional lithography method. Then, the first dielectric layer 204 is etched using the patterned photoresist layer 205 as a mask. The first dielectric layer 204 is etched by dry etching process such as plasma etching or reactive ion etching process to form a first dielectric layer 204 on the P-well.

Referring to FIG. 2C, it is a cross sectional view of a semiconductor substrate illustrating the step of forming the second dielectric layer 206 on the substrate 200 in accordance with the present invention. The second dielectric layer 206 is formed on the portion without first dielectric layer 204 by the thermal oxidation process. That is the second dielectric layer 206 comprising silicon dioxide is formed on the N-well 203. The thickness of the second dielectric layer 206 is about 10 to 300 angstroms. The thickness of the first dielectric layer 204 and second dielectric layer 206 will be different. However, the difference between these two layers is too little to effect the embodiment of the present invention.

Referring to FIG. 2D, it is a cross sectional view of a semiconductor substrate illustrating the step of forming the third dielectric layer 204b on the substrate 200 in accordance with the present invention. The third dielectric layer 204b is formed on the first dielectric layer 204 and the second dielectric layer 206. The thickness of the third dielectric layer 204b is about 10 to 300 angstroms and the material of the third dielectric layer 204b is composed of silicon nitride, which is the same with the first dielectric layer 204.

Referring to FIG. 2E, it is a cross sectional view of a semiconductor substrate illustrating the step of forming the NMOS 213 and PMOS 214 on the substrate 200 in accordance with the present invention. As the traditional method to form MOS, the polysilicon layer 211 is formed over the substrate 200 with the thickness about 1000 to 3500 angstroms and is processed with lithopraphy and etching steps to define the gate electrode. Then, the substrate 200 is processed with LDD method to form L_{DD} region (not shown in the figure) using the gate electrode as a mask. Afterwards, the spacer 209 is formed on the sidewall of the two gate electrode and the source/drain region 207, 208 is formed by ion implantation using the spacer 209 as a mask.

Take a mention that the NMOS 213 comprises the first dielectric layer 204 and third dielectric layer 204b—silicon nitride layer only, and the PMOS 214 comprises the second dielectric layer 206 and third dielectric layer 204b—silicon dioxide and silicon nitride material. However, it is possible to manufacture the variable embodiment based on the spirit of the present invention. For example, by changing the material of the third dielectric layer 304b with the silicon dioxide, the PMOS 214 comprises the silicon dioxide only, and the NMOS 213 comprises the silicon dioxide and silicon nitride.

There still some other variables. For example, the first dielectric layer 204 is formed on the N-well 203 instead of the P-well 202. So, the PMOS 214 comprises silicon nitride layer, and the NMOS 213 comprises the silicon dioxide and silicon nitride material.

From the above description, there are several characteristics in the present invention. Firstly, the second dielectric layer in the present invention is formed by the thermal oxidation method. Therefore, in the processes of forming the gate dielectric layers, there's only one mask needed, which is less than that of the traditional method. Accordingly, comparing with the conventional method, the manufacturing cost and manufacturing time is reduced.

While the invention has been described in terms of a single preferred embodiment, various alternatives and modifications can be devised by those skilled in the art without departing from the invention. Accordingly, the present invention is intended to embrace all such alternatives which fall within the scope of the appended claims.

What is claimed is:

1. A method of manufacturing CMOS with different gate dielectric layers on a substrate, a first part and a second part on said substrate, an isolation region between said first part and second part, said method comprising the steps of:
depositing a first dielectric layer on said first part;
depositing a second dielectric layer on said second part; and
forming a first gate electrode over said first part and a second gate electrode over said second part.

2. The method of claim 1, wherein said first dielectric layer is about in the thickness range about 10 to 300 angstroms.

3. The method of claim 1, wherein said second dielectric layer is about in the thickness range about 10 to 300 angstroms.

4. The method of claim 1, wherein said first dielectric layer and said second dielectric layer comprising different material.

5. The method of claim 4, wherein said first dielectric layer comprising silicon nitride layer by blanket deposition method.

6. The method of claim 4, wherein said second dielectric layer comprising silicon dioxide by thermal oxidation method.

7. The method of claim 1, wherein said first part and said second part are P-well and N-well respectively.

8. A method of manufacturing CMOS with different gate dielectric layers on a substrate, a first part and a second part on said substrate, an isolation region between said first part and second part, said method comprising the steps of:
depositing a first dielectric layer on said first part;
depositing a second dielectric layer on said second part;
depositing a third dielectric layer on said first dielectric layer and said second dielectric layer; and
forming a first gate electrode over said first part and a second gate electrode over said second part.

9. The method of claim 8, wherein said first dielectric layer is about in the thickness range about 10 to 300 angstroms.

10. The method of claim 8, wherein said second dielectric layer is about in the thickness range about 10 to 300 angstroms.

11. The method of claim 8, wherein said third dielectric layer is about in the thickness range about 10 to 300 angstroms.

12. The method of claim 8, wherein said first dielectric layer and said second dielectric layer comprising different material.

13. The method of claim 12, wherein said first dielectric layer comprising silicon nitride layer by blanket deposition method.

14. The method of claim 12, wherein said second dielectric layer comprising silicon dioxide by thermal oxidation method.

15. The method of claim 8, wherein said third dielectric layer comprising the same material with said first dielectric layer.

16. The method of claim 8, wherein said third dielectric layer comprising the same material with said second dielectric layer.

17. The method of claim 8, wherein said first part and said second part are P-well and N-well respectively.
